(19) United States
(12) Patent Application Publication
(10) Pub. No.: US 2026/0282846 A1
(43) Pub. Date: Sep. 17, 2026

(54) METHOD AND APPARATUS FOR HYBRID BONDING

(71) Applicant: TOKYO ELECTRON LIMITED, Tokyo (JP)

(72) Inventors: Mark I. GARDNER, Cedar Creek, TX (US); H. Jim FULFORD, Marianna, FL (US); Partha MUKHOPADHYAY, Oviedo, FL (US); Arkalgud SITARAM, Albany, NY (US); Da YANG, Austin, TX (US)

(73) Assignee: TOKYO ELECTRON LIMITED, Tokyo (JP)

(21) Appl. No.: 19/080,171

(22) Filed: Mar. 14, 2025

(51) Int. Cl. H01L 23/00; H01L 21/66

(52) U.S. Cl. CPC H10P 74/232; H10W 72/071; H10W 80/312; H10W 80/327

(57) ABSTRACT

Aspects of the disclosure provide a hybrid bonding method that includes measuring an electrical characteristic distribution for each of a first wafer and multiple second wafers, the electrical characteristic distribution of each wafer indicating at least one of a distribution of saturation current values of dies of the respective wafer, a distribution of cut-off current values of the dies of the respective wafer, and a distribution of ring oscillator data of the dies of the respective wafer; based on the electrical characteristic distributions of the first wafer and the multiple second wafers, executing a die pairing process that selects a plurality of dies from the multiple second wafers and pairs the selected plurality of dies with the dies of the first wafer to form a plurality of groups of dies; and performing a pick-and-place die-to-chip bonding process to bond the plurality of groups of dies.

### FIELD OF THE INVENTION

The present disclosure relates to semiconductor manufacturing of integrated circuits, and particularly to packaging and stacking of dies as a technique for transistor stacking or 3D formation of semiconductors.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Aspects of the disclosure provide a hybrid bonding method. The hybrid bonding method includes measuring an electrical characteristic distribution for each of a first wafer and multiple second wafers, the electrical characteristic distribution of each wafer indicating at least one of a distribution of saturation current values of dies of the respective wafer, a distribution of cut-off current values of the dies of the respective wafer, and a distribution of ring oscillator data of the dies of the respective wafer; based on the electrical characteristic distributions of the first wafer and the multiple second wafers, executing a die pairing process that selects a plurality of dies from the multiple second wafers and pairs the selected plurality of dies with the dies of the first wafer to form a plurality of groups of dies; and performing a pick-and-place die-to-chip bonding process to bond the plurality of groups of dies.

Aspects of the disclosure provide a semiconductor equipment. The semiconductor equipment includes a controller configured to control a measurement system to measure an electrical characteristic distribution for each of a first wafer and multiple second wafers. The electrical characteristic distribution of each wafer indicates at least one of a distribution of saturation current values of dies of the respective wafer, a distribution of cut-off current values of the dies of the respective wafer, and a distribution of ring oscillator data of the dies of the respective wafer. Based on the electrical characteristic distributions of the first wafer and the multiple second wafers, the controller controls a die pairing system to execute a die pairing process that selects a plurality of dies from the multiple second wafers and pairs the selected plurality of dies with the dies of the first wafer to form a plurality of groups of dies. The controller further controls a bonding system to perform a pick-and-place die-to-chip bonding process to bond the plurality of groups of dies.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIGS. 1A and 1B illustrate electrical characteristics of dies on wafers 110 and 120, respectively, according to some embodiments of the disclosure.

FIG. 2 shows a flow chart of a bonding process according to some embodiments of the disclosure.

FIG. 3A shows a distribution of electrical characteristics of dies on a top wafer according to some embodiments of the disclosure.

FIG. 3B shows a distribution of electrical characteristics of dies on a bottom wafer according to some embodiments of the disclosure.

FIG. 3C shows a schematic view of a die pairing process according to some embodiments of the disclosure.

FIG. 3D shows a schematic view of a die pairing process according to some embodiments of the disclosure.

FIG. 4 shows a flow chart of a process for manufacturing a semiconductor device according to some embodiments of the disclosure.

FIG. 5 shows a bonding equipment according to some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to” includes numerical values at both ends, unless specified otherwise.

Power, Performance, Area, and Cost (PPAC) improvements and Moore's Law's logarithmic performance increases in semiconductor devices have historically progressed primarily through aggressive doubling of transistor count every 18 months enabled by dimensional shrink without regard to functional chip type or the proper management of power scaling and heat dissipation. In the past two decades, as the industry has moved away from fully integrated large silicon area systems on chip (SoCs), it has become increasingly important for continual improvement in semiconductor devices to develop via optimizing PPAC at the system integration level through advanced packaging technologies. These technologies enable different functional chip types (such as “chiplets”) to be integrated into a single package and/or memory chips to be stacked vertically along with controller devices.

An important packaging technology for meeting the industry's ever-increasing needs is hybrid bonding. The hybrid bonding can be typically executed at bond wiring levels or structures of two opposing dies (or wafers). The hybrid bonding can involve bonding a die to a die (referred to as die-to-die or D2D bonding), a die to a wafer (referred to as die-to-wafer or D2W bonding), or a wafer to a wafer (referred to as wafer-to-wafer or W2W bonding). Each of the two opposing dies/wafers (e.g., two opposing dies, two opposing wafers, or one die and one opposing wafer) has a bonding region including exposed or uncovered dielectric material and conductive material (e.g., metal). Thus, through the hybrid bonding, the dielectric materials of the bonding regions of the two opposing dies/wafers can be bonded together, and the metals of the bonding regions of the two opposing dies/wafers can be bonded together, resulting in dielectric-to-dielectric bonds and metal-to-metal bonds. The hybrid bonding can involve an annealing process which results in expansion of the metals of the opposing dies/wafers so that the metals of the bonding regions of the two opposing dies/wafers can be bonded together. After the hybrid bonding, a substrate wafer can then be singulated to produce packaged modules.

The D2D and D2W bonding techniques can allow for a vertical integration of dies. The vertical integration can facilitate the creation of three-dimensional (3D) integrated circuits, which offer significant benefits in terms of increased performance and reduced power consumption. However, the die bonding process is complex and requires a precise control to ensure an optimal performance of the integrated circuits.

One of main challenges for the die bonding process is the selection of the dies to be bonded, which can be referred to as die selection process. The die selection process is crucial for achieving the desired performance characteristics of the integrated circuits. However, related techniques used for the die selection process are not efficient and often result in suboptimal performance.

Additionally, the bonding process itself is also a complex task that requires a precise control to ensure proper alignment and bonding of the dies. Related methods for the die bonding process do not provide a way to intelligently select the dies to be bonded based on the performance characteristics of the dies. This results in a lack of optimization in the performance of the integrated circuits. Furthermore, the related methods do not provide a way to increase the interconnect density or maintain the same net die stack height in the Z dimension, which are critical for achieving high performance and low power consumption.

Further, related die bonder systems do not provide a way to achieve improved energy efficiency in the bonding process. This is a significant drawback, as energy efficiency is a key parameter in the design and operation of the integrated circuits. Furthermore, the related die bonder systems do not provide a way to achieve a significant increase in the interconnect density, which is crucial for achieving high performance and low power consumption.

Therefore, a system or method is needed to overcome the problems discussed above. The system or method can allow for the intelligent selection of dies to be bonded based on the performance characteristics of the dies and thus allow for the optimization of the performance of the integrated circuits. Additionally, the system or method can allow for the increase of interconnect density and the maintenance of the same net die stack height in the Z dimension. Lastly, the system or method can allow for improved energy efficiency in the die bonding process. Such a system or method can represent a significant advancement in the field of integrated circuit design and fabrication.

This disclosure provides systems and methods for vertically bonding multiple dies, by employing an intelligent selective die bonder system. A die selection module of the intelligent selective die bonder system determines a first die from a first wafer and a second die from a second wafer, based upon predictive monitoring for performance, speed, and/or power optimization such as the saturation current (Idsat), cut-off current (Idoff), and ring oscillator data (e.g., speed and/or power consumption of a ring oscillator). A bonding module of the intelligent selective die bonder system then vertically bonds the first die to the second die. This technique allows for an increase in interconnect density and energy efficiency, while maintaining the same net die stack height. The system can optimally pair all die types to be bonded to achieve maximum speed and/or low energy consumption. The disclosure also permits the hybrid bonding of all different types of chips and/or substrates such as GaAs, GaN, SiC, Si, SiGe, and SiO2. SRAM memory (L1, L2, L3 Cache die), DRAM memory, and FLASH Memory are some examples for achieving memory types and die bonding to a base die, advancing circuit performance designs. Furthermore, the disclosure can optimally utilize the output from each wafer, maximizing performance and power from each die, yield, and profit for high volume manufacturing.

In the bonding process, a pick-and-place process refers to a robotic process of grasping a top die, positioning the top die onto a bottom die, and aligning bonding regions of the top die to the corresponding bonding regions of the bottom die, so that the top and bottom dies, which form a pair of dies, can be bonded together. The pick-and-place process can be executed by various robots (e.g., a robotic arm) and is designed to operate in a cleanroom and to significantly reduce manufacturing time and improve manufacturing quality.

Because the bonding process can form electrical connections that electrically connects both the top and bottom dies, ensuring that the electrical connections are aligned and properly formed is crucial for a yield improvement of the hybrid bonding.

For die-to-wafer bonding, a top wafer is diced or cut to generate multiple top dies and one of the multiple top dies is put onto one of multiple bottom dies on a bottom wafer to form a pair of dies for bonding.

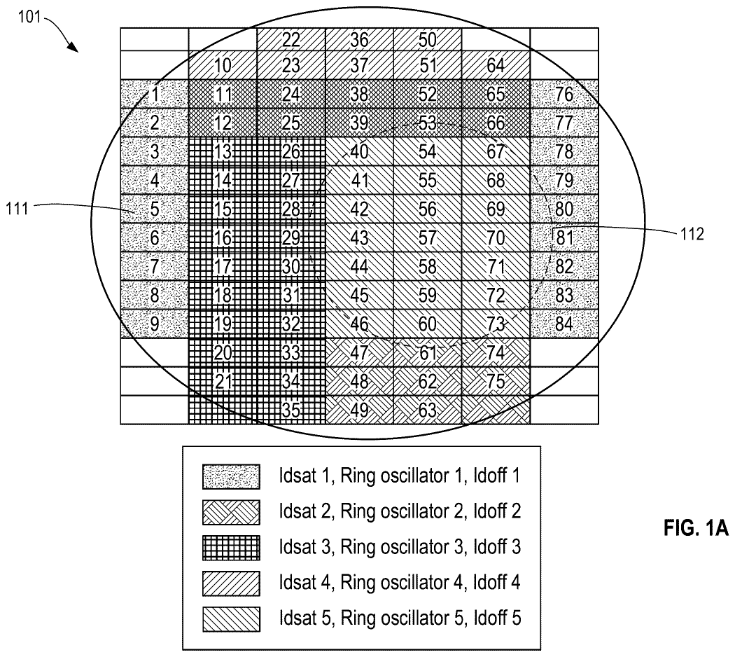

FIGS. 1A and 1B illustrate electrical characteristics of dies on wafers 110 and 120, respectively, according to embodiments of the disclosure. The electrical characteristics of the dies on a wafer can include saturation current values (Idsat) of transistors of the dies, cut-off current values (Idoff) of the transistors of the dies, and/or ring oscillator data of the dies. The saturation current values of the transistors of the dies can be represented by Idsat 1, Idsat 2, Idsat 3, Idsat 4, and Idsat 5. The cut-off current values of the transistors of the dies can be represented by Idoff 1, Idoff 2, Idoff 3, Idoff 4, and Idoff 5. The ring oscillator data of the dies can be represented by Ring oscillator 1, Ring oscillator 2, Ring oscillator 3, Ring oscillator 4, and Ring oscillator 5. Accordingly, the electrical characteristics can be classified into five groups: group 1 (Idsat 1, Idoff 1, Ring oscillator 1), group 2 (Idsat 2, Idoff 2, Ring oscillator 2), group 3 (Idsat 3, Idoff 3, Ring oscillator 3), group 4 (Idsat 4, Idoff 4, Ring oscillator 4), and group 5 (Idsat 5, Idoff 5, Ring oscillator 5). The dies can be represented (or classified) in terms of their electrical characteristics.

First, for two dies respectively on the wafers 110 and 120 having the same relative locations of the wafers, the electrical characteristics of the two dies can be different. For example, a relative location of a die 111 on the wafer 110 is the same as a relative location of a die 121 on the wafer 120, and the dies 111 and 121 have the electrical characteristics of group 1 and group 2, respectively.

Second, the electrical characteristics of the dies on the wafers 110 and 120 have different distributions. Compared to the dies on the wafer 110, the electrical characteristics of the dies on the wafer 120 have a wider dispersion of values, indicating a greater variability in the electrical characteristic across the wafer 120. For example, the dies (within the dotted circle 112 in FIG. 1A) with the electrical characteristics of group 5 (Idsat 5, Idoff 5, Ring oscillator 5) on the wafer 110 locate more clustered compared to the dies on the wafer 120 with the electrical characteristics of group 5.

Accordingly, to obtain the maximum performance for the D2W bonding, an intelligent selective bonder can select a first die and a second die from the wafers 110 and 120, respectively. The first die and the second die have same or similar electrical characteristics. For example, both dies have the same group of electrical characteristics.

In an embodiment, the die sizes can be different between the die from the top wafer and the die from the bottom wafer.

In an embodiment, the die from the top wafer can be a microprocessor and the die from the bottom wafer can be a memory die (e.g., L1, L2, or L3 SRAM cache die) or any circuit or any memory die. It is noted that the roles of the die from the top wafer and the die from the bottom wafer can be reversed as options.

In an embodiment, multiple dies from the top wafer can be bonded to the die on the bottom wafer.

In an embodiment, a stack of multiple tall dies can be bonded to the die on the bottom wafer.

In an embodiment, after the die from the top wafer is bonded to the die on the bottom wafer, the bottom wafer is diced, and the bonded dies can be packaged.

In an embodiment, if the ring oscillator data is not available, paring can be performed with just the saturation current values.

In an embodiment, a wafer map selection of the saturation current measurements can be utilized as opposed to a full wafer mapping for the pairing.

This disclosure can enable circuit performance of a first die be increased by selectively bonding a selective second die to enhance the circuit performance of the vertically bonded dies using an intelligent selective die-to-die bonder method.

Prior art does not provide a method of intelligent bonding to optimize the pairing of the first die to the second die in a vertical bond with the desired performance and power optimization such as Idsat and/or ring oscillator data. To obtain maximum speed performance and low energy consumption, this disclosure enables selective die-to-wafer or die-to-die vertical bonding.

In this disclosure, the second die can be any memory types such as L1, L2, or L3 SRAM caches. The first die or the base die can be a microprocessor die. The second die can be vertically bonded onto the first die to increase the circuit performance increase with a reduced chip area. The L1 cache can be closest to a microprocessor core, and has a fastest bandwidth with a lowest latency. The L2 cache can be a next adjacent cache, and has a next fastest bandwidth and a lower latency compared to the L1 cache, and can have a larger density than the L1 cache. The L3 cache can be an outermost cache from microprocessor core, and has a lower latency compared to the L2 and L3 caches.

It is noted that the first and second dies are not limited in this disclosure. In an embodiment, the first die can be a memory die and the second die can be a microprocessor die.

The techniques provided by this disclosure can best utilize the entire output for the entire wafer with the different Idsat, ring oscillator data, and performance of each die to be vertically bonded together for multiple circuit applications. This enables a better utilization of all dies from all wafers to maximize circuit performance, reduce power, and improve yield and profit for high volume manufacturing (HVM).

This disclosure provides an intelligent selective die bonder system that enhances the performance of vertically bonded 3D circuits by selectively bonding a first die (D1) with a certain transistor and circuit performance to a selective second die (D2).

This disclosure also provides a method of intelligent bonding that optimizes the pairing of D1 to D2 in a vertical bond with the desired Idsat and ring oscillator performance to achieve maximum speed and low energy consumption.

This disclosure also provides an interconnect density increase of more than 100 times through the bonding of D1 and D2, thus extending the optimum multiple core systems with higher performance for multiple bonded vertically bonded dies.

This disclosure also provides more than 2 times interconnect energy efficiency and improve performance compared to a non-intelligent selective multiple die bonder.

According to one aspect of the disclosure, an intelligent selective die bonder system is configured for bonding multiple dies. The system includes a selection module configured to select a first die from a first wafer and a second die from a second wafer based on Idsat and ring oscillator values. The bonding module of the system is configured to vertically bond the first die to the second die. In some embodiments, the first wafer may be a microprocessor die and the second wafer may be a memory die. The selection module may be further configured to select multiple second dies from the second wafer for bonding to the first die. The bonding module may be further configured to bond a stack of N dies to the first die.

According to another aspect of the disclosure, the selection module is further configured to perform a die pairing process based on Idsat values if no ring oscillator data is available. The selection module may also use a wafer map selection of Idsat measurements for the die pairing process. The selection module may select the first die and the second die with the aim of achieving maximum speed and low energy consumption. The bonding module may achieve an interconnect density increase of more than 100 times through the bonding of the first die and the second die. The bonding module may achieve more than 2 times interconnect energy efficiency compared to a non-intelligent selective multiple die bonder. The bonding module may also maintain the same net die stack height in the heigh (or Z) dimension.

A method for bonding multiple dies using an intelligent selective die bonder system is also provided. The method comprises selecting a first die from a first wafer and a second die from a second wafer based on the saturation current Idsat and the ring oscillator values (e.g., speed or power consumption), and vertically bonding the first die to the second die.

The method may also involve selecting multiple second dies from the second wafer for bonding to the first die, bonding a stack of N dies to the first die, performing a die pairing process based on Idsat values if no ring oscillator data is available, using a wafer map selection of Idsat measurements for the die pairing process, selecting the first die and the second die with the aim of achieving maximum speed and low energy consumption, achieving an interconnect density increase of more than 100 times through the bonding of the first die and the second die, achieving more than 2 times interconnect energy efficiency compared to a non-intelligent selective multiple die bonder, and maintaining the same net die stack height in the Z dimension.

This disclosure provides an intelligent selective die bonder system configured for bonding multiple dies. The system includes a selection module configured to select a first die from a first wafer and a second die from a second wafer based on predictive performance, speed, and/or low power consumption, or any desired device or circuit property. The system further includes a bonding module configured to vertically bond the first die to the second die.

In an embodiment, the selection module is configured to select the first die from the first wafer and the second die from the second wafer based on Idsat, Idoff, and ring oscillator values of the first and second dies. The bonding module is configured to vertically bond the first die to the second die.

In an embodiment, the first wafer includes any circuit such as central processing unit (CPU) or memory dies (e.g., SRAM) and the second wafer includes any circuit or memory dies.

In an embodiment, the first die is a microprocessor die and the second die is a memory die.

In an embodiment, the first die is a memory die and the second die is a memory die.

In an embodiment, the selection module is further configured to select multiple second dies from the second wafer for bonding to the first die.

In an embodiment, the bonding module is further configured to bond a stack of multiple dies to the first die.

In an embodiment, the selection module is further configured to perform a die pairing process based on Idsat values if no ring oscillator data is available.

In an embodiment, the selection module is further configured to use a wafer map selection of Idsat measurements for the die pairing process.

In an embodiment, the selection module is further configured to select the first die and the second die with the aim of achieving maximum speed and low energy consumption.

In an embodiment, the bonding module is further configured to achieve an interconnect density increase of more than 100 times through the bonding of the first die and the second die.

In an embodiment, the bonding module is further configured to achieve more than 2 times interconnect energy efficiency compared to a non-intelligent selective multiple die bonder.

In an embodiment, the bonding module is further configured to maintain the same net die stack height in the Z dimension.

This disclosure provides a method for bonding multiple dies using an intelligent selective die bonder system. The method includes selecting a first die from a first wafer and a second die from a second wafer based on Idsat and ring oscillator values of the first and second dies, and vertically bonding the first die to the second die.

In an embodiment, the first die is any circuit die (e.g., CPU) and the second die is a memory die (e.g., SRAM).

In an embodiment, the first die is a microprocessor die (e.g., CPU) and the second die is a memory die (e.g., SRAM).

In an embodiment, the method including selecting multiple second dies from the second wafer for bonding to the first die.

In an embodiment, the method including bonding a stack of multiple dies to the first die.

In an embodiment, the method including performing a die pairing process based on the Idsat values if no ring oscillator data is available.

In an embodiment, the method including using a wafer map selection of the Idsat measurements for the die pairing process.

In an embodiment, the method including selecting the first die and the second die with the aim of achieving maximum speed and low energy consumption.

In an embodiment, the method including achieving an interconnect density increase of more than 100 times through the bonding of the first die and the second die.

In an embodiment, the method including achieving more than 2 times interconnect energy efficiency compared to a non-intelligent selective multiple die bonder.

In an embodiment, the method further including maintaining the same net die stack height in the Z dimension.

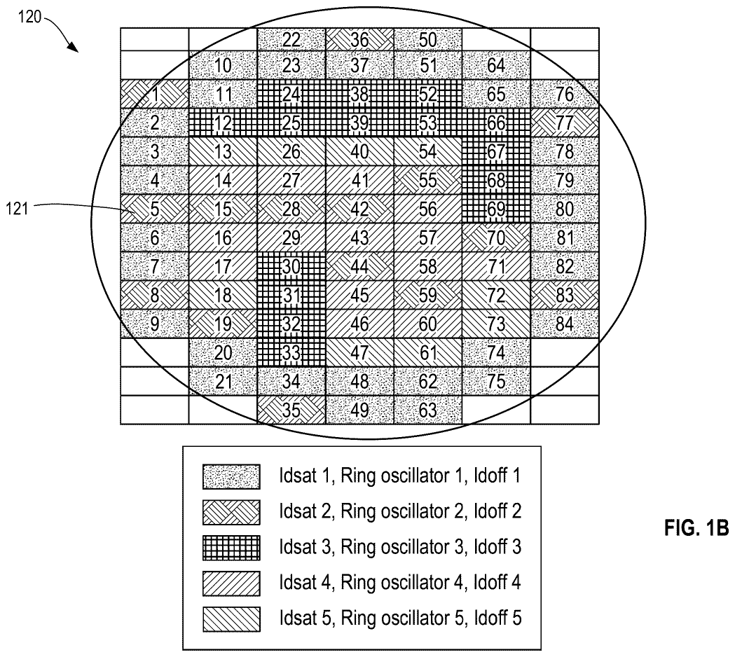

FIG. 2 shows a flow chart of a process 200 for hybrid bonding, in accordance with some embodiments of the present disclosure. At step S201, the process 200 can collect (e.g., through a measurement) saturation current values and cut-off current values of transistors and ring oscillator data from a first wafer (also referred to as a bottom wafer) and multiple second wafers (also referred to as top wafers). The dies on the bottom wafer are referred to as bottom dies, and the dies on the top wafers are referred to as top dies. The measurement can be done for each die on the wafers or for a part of the dies on the wafers. At step S203, the process 200 can calculate the overlay saturation current values, ring oscillator data, and cut-off current values of optimum bonding pairing. At step S205, the process 200 can employ a feedback control artificial intelligence (AI) algorithm (e.g., a decision-making algorithm) to pick the top dies from the top wafers. At step S207, the process 200 can perform a pick-and-place die-to-chip bonding process. For instance, for each bottom die on the bottom wafer, a top die is picked and placed onto the respective bottom die based on the calculated overlay registration and the proximity of Cu recess depth, so that each bottom die on the bottom wafer has a top die placed on the respective bottom die. At step S209, the process 200 can obtain feedback through yield and performance of the bonded dies. At step S211, the process 200 can optimize the performance with an intelligent electrical alignment. At step S213, the process 200 can perform an optimized pick-and-place die-to-chip bonding process for improved D2D and D2W performance enhancement.

In an embodiment, a controller 190 may be coupled to various components of the process 200 to receive inputs from and provide outputs to the components. For example, the controller 190 can be configured to implement the steps S201, S203, S205, S207, S209, S211 and/or S213. In an embodiment, one or more functions of the controller 190 can also be manually accomplished.

In some embodiments, the controller 190 may include a memory storage unit and user interface (all not shown). Components of a semiconductor processing tool (e.g. a bonding tool, a registration metrology tool, etc.) can be connected to and controlled by the controller 190. Various wafer-processing operations can be executed via the user interface, and various wafer processing recipes and operations can be stored in the storage unit.

In an embodiment, the controller 190 may be coupled to various components of various semiconductor processing tools to receive inputs from and provide outputs to the various components. For example, the controller 190 can be configured to receive overlay registration data from a corresponding registration metrology tool. The controller 190 can also be configured to pick a top die from a dicing tape and place the top die onto a bottom die by controlling a robotic arm. The controller 190 can further be configured to adjust knobs and control settings for the corresponding bonding tool. Such adjustments can be manually made as well.

The controller 190 can be implemented in a wide variety of manners. In an example, the controller 190 includes a computer. In an example, the controller 190 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a semiconductor processing recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations can also be implemented.

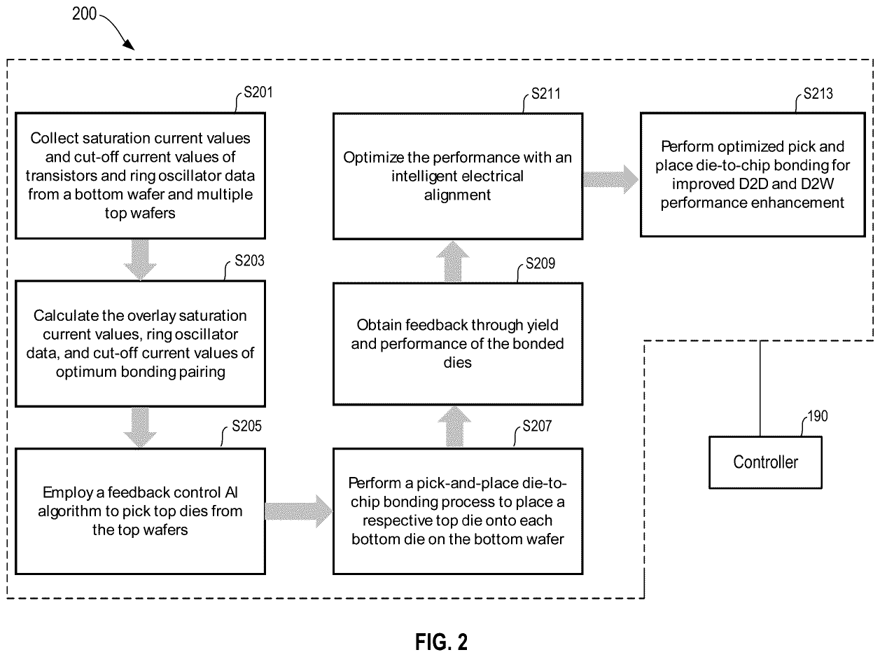

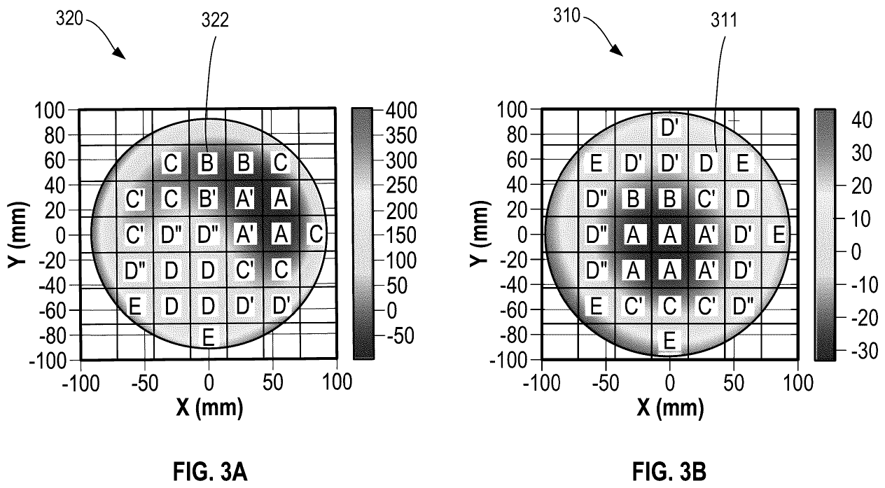

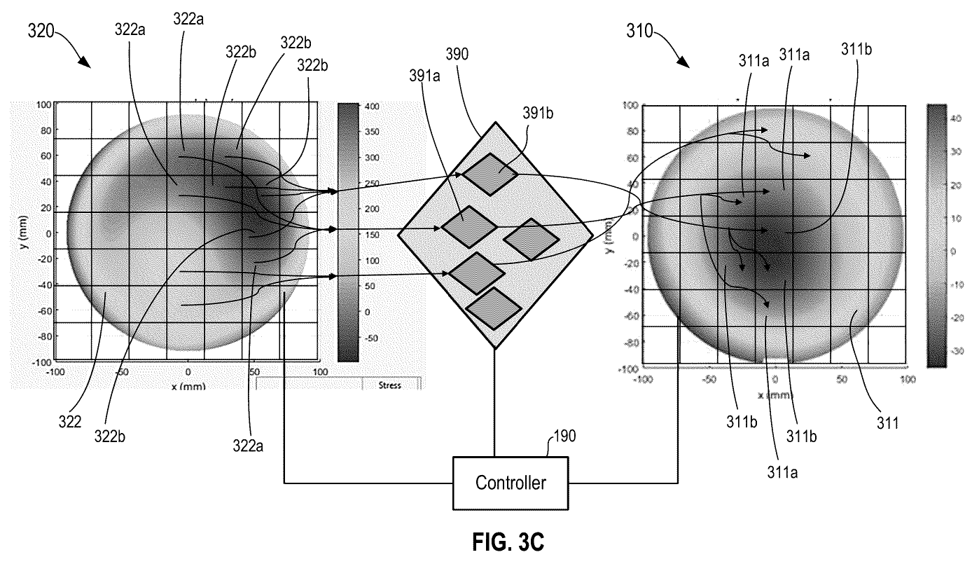

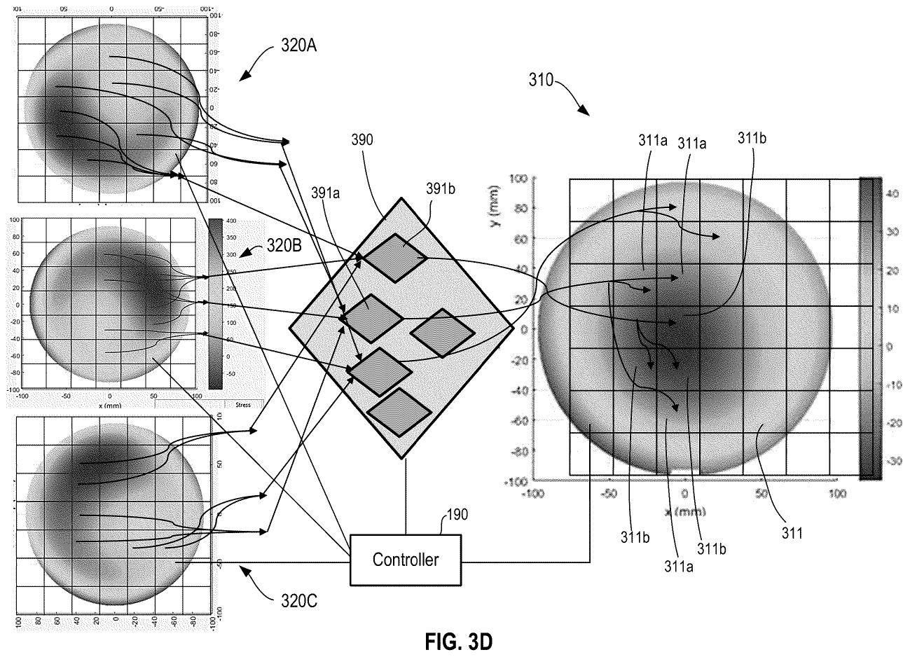

FIG. 3A shows a distribution of electrical characteristics of dies on a top wafer (also referred to as a second wafer 320 hereinafter), and FIG. 3B shows a distribution of electrical characteristics of dies on a bottom wafer (also referred to as a first wafer 310 hereinafter), in accordance with some embodiments of the present disclosure. The electrical characteristics can include the saturation current (Idsat), cut-off current (Idoff), and/or ring oscillator data (e.g., speed and/or power consumption of a ring oscillator).

The first wafer 310 includes a plurality of first dies 311 arranged in a grid pattern. First electrical characteristics of the first dies 311 can be measured through an automated parametric tester (APT) for example and can be mapped across the first wafer 310. The first dies 311 can be divided into groups based on respective first electrical characteristics.

In the example of FIG. 2B, the first dies 311 can be divided into Group A, Group A′, Group B, Group B′, Group C, Group C′, Group D, Group D′, Group D″, and Group E, where each group may include one or more of the first dies 311. Respective dies within each group have respective first electrical characteristics that are close to each other, e.g. within a predetermined range.

The second wafer 320 includes a plurality of second dies 322 arranged in a grid pattern. Second electrical characteristics of the second dies 322 can be measured by the same APT as the first electrical characteristics or different APT, and can be mapped across the second wafer 320. The second dies 322 can be divided into groups based on respective second electrical characteristics.

In the example of FIG. 2A, the second dies 322 can be divided into Group A, Group A′, Group B, Group B′, Group C, Group C′, Group D, Group D′, Group D″, and Group E, where each group may include one or more of the second dies 322. Respective dies within each group have second electrical characteristics that are close to each other, e.g. within a predetermined range.

Here, groups of the first dies 311 and groups of the second dies 322 are designated the same letter for having the same or similar electrical characteristics. For instance, respective first electrical characteristics of Group A of the first dies 311 are within a first range while respective second electrical characteristics of Group A of the second dies 322 are within a second range. The first range and the second range can be the same as each other or close to each other such that Group A of the first dies 311 and Group A of the second dies 322 can be treated as having substantially the same electrical characteristics for subsequent processing. Similarly, Group B of the first dies 311 and Group B of the second dies 322 can be treated as having substantially the same electrical characteristics for subsequent processing. More generally speaking, preferred matching for the electrical characteristics can be A to A/A′, or B to B/B′, C to C/C′, or D to D/D′3 /D″, etc. On the other hand, pairing a die from Group B of the second dies 322 with a die from Group A or A′ of the first dies 311 can lead to low device performance. The low device performance can become more problematic as the reduction of feature sizes.

Note that although FIGS. 3A and 3B show that the first wafer 310 and the second wafer 320 have different distributions of the electrical characteristics, the first wafer 310 and the second wafer 320 can have the same distribution of the electrical characteristics in an embodiment.

Further, FIGS. 3A and 3B only show one embodiment of dividing the first dies 311 and/or the second dies 322 into groups for illustrative purposes. In other embodiments, depending on specific design needs, the first dies 311 and/or the second dies 322 can be divided into groups differently, for example as will be demonstrated in FIG. 2C.

FIG. 3C shows a schematic view of a die pairing process in accordance with some embodiments of the present disclosure. Herein, the first dies 311 are divided into a first group represented by first dies 311a, a second group represented by first dies 311b, and other groups based on respective first electrical characteristics. The respective first electrical characteristics of the first dies 311 can be measured for example by the APT, which may further be controlled by the controller 190 and stored in the controller 190.

The controller 190 can include a decision-making algorithm 290 that stores electrical characteristics values and/or ranges (e.g. 291a, 291b, etc.) corresponding to groups of the first dies (e.g. 311a, 311b, etc.). The controller 190 can also collect and store respective second electrical characteristics of the second dies 322. The decision-making algorithm 290 can compare the (stored) electrical characteristics ranges (e.g. 291a, 291b, etc.) with the second electrical characteristics and accordingly divide the second dies 322 into a first group represented by second dies 322a, a second group represented by second dies 322b, and other groups. For instance, the first group of the first dies represented by the first dies 311a and the first group of the second dies represented by the second dies 322a can be matched and paired for having respective electrical characteristics within a first electrical characteristics range 291a. The second group of the first dies represented by the first dies 311b and the second group of the second dies represented by the second dies 322b can be matched and paired for having respective electrical characteristics within a second electrical characteristics range 291b.

As a result, any one of the second dies 322a can be picked from the second wafer 320 and placed onto any one of the first dies 311a to form a respective pair for example by a robotic arm controlled by the controlled 190. Similarly, any one of the second dies 322b can be picked from the second wafer 320 and placed onto any one of the first dies 311b to form a respective pair.

In this example, the first dies 311 can be used as bottom dies while the second dies 322 can be used as top dies. That is, the second dies 322 are flipped upside down and placed on top of the first dies 311 so that the first dies 311 and the second dies 322 are oriented face to face. For example, a face side (e.g. circuitry) of the first dies 311 and a face side (e.g. circuitry) of the second dies 322 face towards each other while a back side (e.g. bulk semiconductor material) of the first dies 311 and a back side (e.g. bulk semiconductor material) of the second dies 322 face away from each other.

Note that the second dies 322 have initial relative positions with regard to each other on the second wafer 320. However, after the die pairing or pick-and-place process, the second dies 322 are placed on respective first dies 311 and may have changed relative positions with regard to each other. For instance, two neighboring second dies 322 on the second wafer 320 may not be neighboring to each other after die pairing or pick-and-place process.

In the examples of FIGS. 2A-2C, the first wafer 310 and the second wafer 320 both have a wafer diameter of 200 mm. Generally speaking, the first wafer 310 and the second wafer 320 may each independently have a wafer diameter of 50 mm, 75 mm, 100 mm, 125 mm, 150 mm, 200 mm, 300 mm, or 450 mm. Preferably, the first wafer 310 and the second wafer 320 each independently have a wafer diameter of 150 mm, 200 mm, or 300 mm. Additionally, the first wafer 310 and the second wafer 320 may or may not have a same wafer diameter.

Note that dimensions of various wafer diameters are mentioned herein merely for illustrative purposes and are not limiting. As a skilled artisan would understand, wafer diameters can also be expressed in inches, and a value expressed in millimeters and a value expressed in inches for a same wafer are not always equal to each other. For instance, 50 mm, 75 mm, 100 mm, 125 mm, 150 mm, 200 mm, 300 mm, and 450 mm may respectively be known as 2 inches, 3 inches, 4 inches, 5 inches, 6 inches, 8 inches, 12 inches, and 18 inches. However, 300 mm=11.811 inches, not exactly 12 inches. 200 mm=7.874 inches, not exactly 8 inches. Therefore, a value of a wafer diameter in the present disclosure generally represents a range of the value * (100%±10%), preferably the value * (100%±5%), preferably the value * (100%±3%), preferably the value. For instance, a wafer diameter of 200 mm represents a range of 180 mm to 220 mm, preferably 190 mm to 210 mm, preferably 194 mm to 206 mm, preferably 200 mm.

In a non-limiting example, a plasma activation process can be performed on the first dies 311 and the second dies 322, and deionized water (DIW) may be used to rinse the first dies 311 and the second dies 322. Then the first dies 311 and the second dies 322 can be aligned and pre-bonded. Pre-bonded dies may be inspected, for example using infrared light transmission imaging, and can be stripped and cleaned. The pre-bonded dies can further be bonded for instance by an annealing process. As a result, respective dielectric materials of the first dies 311 and the second dies 322 bond with each other and respective metal materials of the first dies 311 and the second dies 322 expand to bond with each other. It should be understood that the first dies 311 and the second dies 322 may alternatively be bonded by other processes or techniques such as direct bonding, surface-activated bonding, plasma-activated bonding, anodic bonding, eutectic bonding, glass frit bonding, adhesive bonding, reactive bonding, transient liquid phase diffusion bonding, and/or the like.

In the example of FIG. 2C, there are three of the first dies 311a and three of the first dies 311b while there are three of the second dies 322a and four of the second dies 322b. Therefore, the first dies 311a and the first dies 311b can each find a respective match from dies sourced from the second wafer 320 to form a respective pair. In other examples, the second dies 322a may be fewer than the first dies 311a. Additionally or alternatively, the second dies 322b may be fewer than the first dies 311b. Accordingly, one or more additional second wafers may be needed to provide dies for the first dies 311a and/or the first dies 311b. In some embodiments, one or more of the first dies 311 may have respective first electrical characteristics that cannot be matched or paired with any of the second dies 322. Accordingly, one or more additional second wafers will be needed.

Referring back to FIGS. 2A and 2B, there are four dies in Group A, two dies in Group A′, two dies in Group B, zero die in Group B′, one die in Group C, two dies in Group C′, two dies in Group D, five dies in Group D′, four dies in Group D″, and five dies in Group E in the first dies 311. There are two dies in Group A, two dies in Group A′, two dies in Group B, one die in Group B′, four dies in Group C, three dies in Group C′, four dies in Group D, two dies in Group D′, three dies in Group D″, and two dies in Group E in the second dies 322. Therefore, not all of the first dies 311 can find a match with the second dies 322. Accordingly, one or more additional second wafers will be needed.

FIG. 3D shows a schematic view of a die pairing process in accordance with some embodiments of the present disclosure. Herein, a plurality of second wafers for example represented by 320A, 320B and 320C are used to provide top dies for the first dies 311 sourced from the first wafer 310. For instance, one or more dies, which have respective electrical characteristics that fall within the first electrical characteristics range 291a, can be sourced from each of the second wafers 320A, 320B, and 320C, and can be paired with the first dies 311a. Similarly, one or more dies, which have respective electrical characteristics that fall within the second electrical characteristics range 291b, can be sourced from each of the second wafers 320A, 320B, and 320C, and can be paired with the first dies 311b.

Here, there are four dies in Group A, two dies in Group A′, two dies in Group B, zero die in Group B′, one die in Group C, two dies in Group C′, two dies in Group D, five dies in Group D′, four dies in Group D″, and five dies in Group E in the first dies 311. There are six dies in Group A, six dies in Group A′, six dies in Group B, three dies in Group B′, twelve dies in Group C, nine dies in Group C′, twelve dies in Group D, six dies in Group D′, nine dies in Group D″, and six dies in Group E for the second wafers 320A, 320B, and 320C. Therefore, each of the first dies 311 can find a respective match with dies sourced from the second wafers 320A, 320B, and 320C.

The controller 190 can be configured to measure respective second electrical characteristics of second dies sourced from the second wafers 320A, 320B, and 320C, and to store the respective second electrical characteristics. The decision-making algorithm 290 can compare the electrical characteristics ranges (e.g., 291a, 291b, and etc.) with the second electrical characteristics and accordingly divide second dies sourced from the second wafers 320A, 320B, and 320C into groups to match and pair with the first dies 311.

Note that the drawings of the present disclosure are not necessarily drawn to scale. Particularly in the example of FIG. 2D, the first wafer 310 and the second wafers 320A, 320B, and 320C all have a same wafer diameter of 200 mm. Generally speaking, the first wafer 310 and the second wafers 320A, 320B, and 320C may each independently have a wafer diameter of 50 mm, 75 mm, 100 mm, 125 mm, 150 mm, 200 mm, 300 mm, or 450 mm. Preferably, the first wafer 310 and the second wafers 320A, 320B, and 320C each independently have a wafer diameter of 150 mm, 200 mm, or 300 mm. Additionally, the first wafer 310 and the second wafers 320A, 320B, and 320C may or may not have a same wafer diameter. In this example, the second wafers 320A, 320B, and 320C have the same electrical characteristics distribution. In other examples, at least two of the second wafers 320A, 320B, and 320C can have different electrical characteristics distributions.

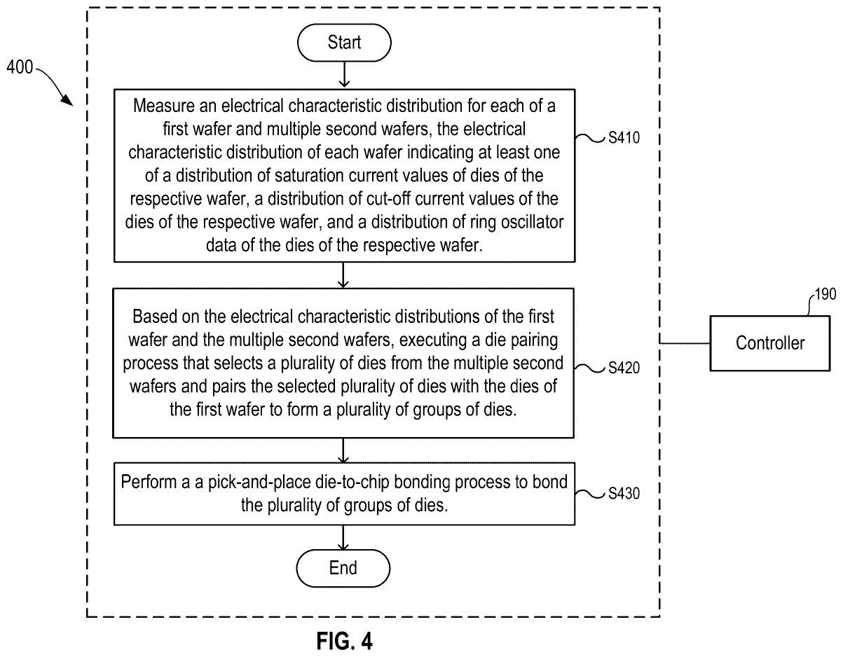

FIG. 4 shows a flow chart of a process for manufacturing a semiconductor device in accordance with some embodiments of the present disclosure. In various embodiments, some of the steps of the process 400 shown can be performed concurrently or in a different order than shown, can be substituted by other method steps, or can be omitted. Additional method steps can also be performed as desired.

Starting at S410, the process 400 can measure an electrical characteristic distribution for each of a first wafer and multiple second wafers. The electrical characteristic distribution of each wafer indicates at least one of a distribution of saturation current values of dies of the respective wafer, a distribution of cut-off current values of the dies of the respective wafer, and a distribution of ring oscillator data of the dies of the respective wafer.

At step S420, the process 400 can based on the electrical characteristic distributions of the first wafer and the multiple second wafers, execute a die pairing process that selects a plurality of dies from the multiple second wafers and pairs the selected plurality of dies with the dies of the first wafer to form a plurality of groups of dies.

At step S430, the process 400 can perform a pick-and-place die-to-chip bonding process to bond the plurality of groups of dies.

It can be recognized that the controller 190 may be coupled to various components of the process 400 to receive inputs from and provide outputs to the components. For example, the controller 190 can be configured to implement steps S410, S420, and/or S430. Of course, one or more functions of the controller 190 can also be manually accomplished.

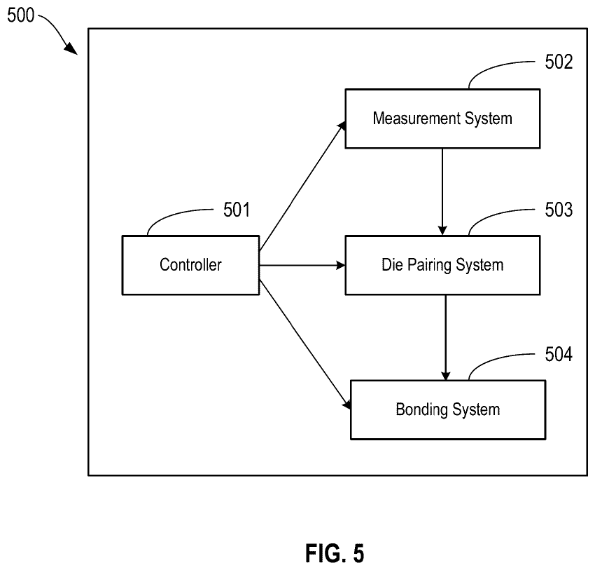

FIG. 5 shows a bonding equipment 500 in accordance with some embodiments of the present disclosure. The bonding equipment 500 includes a controller 501, a measurement system 502, a die pairing system 503, and a bonding system 604. The measurement system 502 can measure an electrical characteristic distribution for each of a first wafer and multiple second wafers. The electrical characteristic distribution of each wafer indicates at least one of a distribution of saturation current values of dies of the respective wafer, a distribution of cut-off current values of the dies of the respective wafer, and a distribution of ring oscillator data of the dies of the respective wafer. Based on the electrical characteristic distributions of the first wafer and the multiple second wafers, the die pairing system 503 can execute a die pairing process that selects a plurality of dies from the multiple second wafers and pairs the selected plurality of dies with the dies of the first wafer to form a plurality of groups of dies. The bonding system 504 can execute a pick-and-place die-to-chip bonding process to bond the plurality of groups of dies.

In an embodiment, the bonding equipment 500 can include a wafer dicing system that dices a wafer into a plurality of dices and a die handling system that picks and places the plurality of dies to corresponding positions.

In an embodiment, the controller 501 can control operations of the wafer dicing system, the die handling system, the measurement system 502, the die pairing system 503, and the bonding system 504.

Aspects of the disclosure provide a hybrid bonding method. The hybrid bonding method includes measuring an electrical characteristic distribution for each of a first wafer and multiple second wafers, the electrical characteristic distribution of each wafer indicating at least one of a distribution of saturation current values of dies of the respective wafer, a distribution of cut-off current values of the dies of the respective wafer, and a distribution of ring oscillator data of the dies of the respective wafer; based on the electrical characteristic distributions of the first wafer and the multiple second wafers, executing a die pairing process that selects a plurality of dies from the multiple second wafers and pairs the selected plurality of dies with the dies of the first wafer to form a plurality of groups of dies; and performing a pick-and-place die-to-chip bonding process to bond the plurality of groups of dies.

In an embodiment, in the hybrid bonding method, each group of dies includes a first die from the first wafer and one or more second dies from the second wafers.

In an embodiment, in the hybrid bonding method, the pick-and-place die-to-chip bonding process is to bond the one or more second dies from the second wafers vertically onto the first die from the first wafer for each group of dies.

In an embodiment, in the hybrid bonding method, the first die from the first wafer has a first electrical characteristic value and each second die from the second wafers has a respective second electrical characteristic value, the die pairing process is executed such that a difference between the first electrical characteristic value and each second electrical characteristic value is within an electrical characteristic threshold.

In an embodiment, in the hybrid bonding method, the die pairing process includes: calculating an overlay electrical characteristic value for each first die of the first wafer based on the electrical characteristic distribution of the first wafer; and performing a feedback control artificial intelligent algorithm to select one or more second dies from the second wafers for each first die.

In an embodiment, in the hybrid bonding method, the overlay electrical characteristic value includes at least one of a saturation current value, a cut-off current value, a ring oscillator speed value, or a ring oscillator power consumption value.

In an embodiment, in the hybrid bonding method, the die pairing process is executed based on a yield analysis of previous bonding data.

In an embodiment, in the hybrid bonding method, the dies of the first wafer are microprocessor dies and the dies of the second wafers are memory dies.

In an embodiment, the hybrid bonding method further includes: optimizing the pick-and-place die-to-chip bonding process; and performing an optimized pick-and-place die-to-chip bonding process.

In an embodiment, in the hybrid bonding method, the electrical characteristic distributions are measured using a wafer map selection technique.

Aspects of the disclosure provide a semiconductor equipment. The semiconductor equipment includes a controller configured to control a measurement system to measure an electrical characteristic distribution for each of a first wafer and multiple second wafers. The electrical characteristic distribution of each wafer indicates at least one of a distribution of saturation current values of dies of the respective wafer, a distribution of cut-off current values of the dies of the respective wafer, and a distribution of ring oscillator data of the dies of the respective wafer. Based on the electrical characteristic distributions of the first wafer and the multiple second wafers, the controller controls a die pairing system to execute a die pairing process that selects a plurality of dies from the multiple second wafers and pairs the selected plurality of dies with the dies of the first wafer to form a plurality of groups of dies. The controller further controls a bonding system to perform a pick-and-place die-to-chip bonding process to bond the plurality of groups of dies.

In an embodiment, each group of dies includes a first die from the first wafer and one or more second dies from the second wafers.

In an embodiment, the pick-and-place die-to-chip bonding process is to bond the one or more second dies from the second wafers vertically onto the first die from the first wafer for each group of dies.

In an embodiment, the first die from the first wafer has a first electrical characteristic value and each second die from the second wafers has a respective second electrical characteristic value, the die pairing process is executed such that a difference between the first electrical characteristic value and each second electrical characteristic value is within an electrical characteristic threshold.

In an embodiment, the die pairing process includes: calculating an overlay electrical characteristic value for each first die of the first wafer based on the electrical characteristic distribution of the first wafer; and performing a feedback control artificial intelligent algorithm to select one or more second dies from the second wafers for each first die.

In an embodiment, the overlay electrical characteristic value includes at least one of a saturation current value, a cut-off current value, a ring oscillator speed value, or a ring oscillator power consumption value.

In an embodiment, the die pairing process is executed based on a yield analysis of previous bonding data.

In an embodiment, the dies of the first wafer are microprocessor dies and the dies of the second wafers are memory dies.

In an embodiment, the controller controls the bonding system to optimize the pick-and-place die-to-chip bonding process, and perform an optimized pick-and-place die-to-chip bonding process.

In an embodiment, the electrical characteristic distributions are measured using a wafer map selection technique.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A hybrid bonding method, comprising:
measuring an electrical characteristic distribution for each of a first wafer and multiple second wafers, the electrical characteristic distribution of each wafer indicating at least one of a distribution of saturation current values of dies of the respective wafer, a distribution of cut-off current values of the dies of the respective wafer, and a distribution of ring oscillator data of the dies of the respective wafer;
based on the electrical characteristic distributions of the first wafer and the multiple second wafers, executing a die pairing process that selects a plurality of dies from the multiple second wafers and pairs the selected plurality of dies with the dies of the first wafer to form a plurality of groups of dies; and
performing a pick-and-place die-to-chip bonding process to bond the plurality of groups of dies.

2. The hybrid bonding method of claim 1, wherein each group of dies includes a first die from the first wafer and one or more second dies from the second wafers.

3. The hybrid bonding method of claim 2, wherein the pick-and-place die-to-chip bonding process is to bond the one or more second dies from the second wafers vertically onto the first die from the first wafer for each group of dies.

4. The hybrid bonding method of claim 2, wherein the first die from the first wafer has a first electrical characteristic value and each second die from the second wafers has a respective second electrical characteristic value, the die pairing process is executed such that a difference between the first electrical characteristic value and each second electrical characteristic value is within an electrical characteristic threshold.

5. The hybrid bonding method of claim 1, wherein the die pairing process includes:
calculating an overlay electrical characteristic value for each first die of the first wafer based on the electrical characteristic distribution of the first wafer; and
performing a feedback control artificial intelligent algorithm to select one or more second dies from the second wafers for each first die.

6. The hybrid bonding method of claim 5, wherein the overlay electrical characteristic value includes at least one of a saturation current value, a cut-off current value, a ring oscillator speed value, or a ring oscillator power consumption value.

7. The hybrid bonding method of claim 1, wherein the die pairing process is executed based on a yield analysis of previous bonding data.

8. The hybrid bonding method of claim 1, wherein the dies of the first wafer are microprocessor dies and the dies of the second wafers are memory dies.

9. The hybrid bonding method of claim 1, further comprising:
optimizing the pick-and-place die-to-chip bonding process; and
performing an optimized pick-and-place die-to-chip bonding process.

10. The hybrid bonding method of claim 1, wherein the electrical characteristic distributions are measured using a wafer map selection technique.

11. A semiconductor equipment, comprising:
a controller configured to
control a measurement system to measure an electrical characteristic distribution for each of a first wafer and multiple second wafers, the electrical characteristic distribution of each wafer indicating at least one of a distribution of saturation current values of dies of the respective wafer, a distribution of cut-off current values of the dies of the respective wafer, and a distribution of ring oscillator data of the dies of the respective wafer;
based on the electrical characteristic distributions of the first wafer and the multiple second wafers, control a die pairing system to execute a die pairing process that selects a plurality of dies from the multiple second wafers and pairs the selected plurality of dies with the dies of the first wafer to form a plurality of groups of dies; and
control a bonding system to perform a pick-and-place die-to-chip bonding process to bond the plurality of groups of dies.

12. The semiconductor equipment of claim 11, wherein each group of dies includes a first die from the first wafer and one or more second dies from the second wafers.

13. The semiconductor equipment of claim 12, where the pick-and-place die-to-chip bonding process is to bond the one or more second dies from the second wafers vertically onto the first die from the first wafer for each group of dies.

14. The semiconductor equipment of claim 12, wherein the first die from the first wafer has a first electrical characteristic value and each second die from the second wafers has a respective second electrical characteristic value, the die pairing process is executed such that a difference between the first electrical characteristic value and each second electrical characteristic value is within an electrical characteristic threshold.

15. The semiconductor equipment of claim 11, wherein the die pairing process includes:
calculating an overlay electrical characteristic value for each first die of the first wafer based on the electrical characteristic distribution of the first wafer; and
performing a feedback control artificial intelligent algorithm to select one or more second dies from the second wafers for each first die.

16. The semiconductor equipment of claim 15, wherein the overlay electrical characteristic value includes at least one of a saturation current value, a cut-off current value, a ring oscillator speed value, or a ring oscillator power consumption value.

17. The semiconductor equipment of claim 11, wherein the die pairing process is executed based on a yield analysis of previous bonding data.

18. The semiconductor equipment of claim 11, wherein the dies of the first wafer are microprocessor dies and the dies of the second wafers are memory dies.

19. The semiconductor equipment of claim 11, wherein the controller controls the bonding system to:
optimize the pick-and-place die-to-chip bonding process; and
perform an optimized pick-and-place die-to-chip bonding process.

20. The semiconductor equipment of claim 11, wherein the electrical characteristic distributions are measured using a wafer map selection technique.
